(19) United States
(12) Patent Application Publication
(10) Pub. No.: US 2006/0097382 A1
(43) Pub. Date: May 11, 2006

(54) High frequency module

(75) Inventors: Kazuhito Mori, Kawanishi-shi (JP); Toshiyuki Munemasa, Miyoshi-shi (JP)

Correspondence Address: BIRCH STEWART KOLASCH & BIRCH, PO BOX 747, FALLS CHURCH, VA, 22040-0747, US

(73) Assignee: MIYOSHI ELECTRONICS CORPORATION

(21) Appl. No.: 11/313,808

(22) Filed: Dec. 22, 2005

(30) Foreign Application Priority Data
Nov. 20, 2003 (JP) 2003-390798(P)

(51) Int. Cl. H01L 23/34

(52) U.S. Cl. 257/706

(57) ABSTRACT

A high frequency module includes an insulating substrate, an upper layer plated pattern (a signal line) formed on a main surface of the insulating substrate and electrically connected to a high frequency circuit to transmit a high frequency signal, a mounted part (an electronic component) mounted on the main surface of the insulating substrate and connected to the upper layer plated pattern, a metal heat sink plate (a heat sink plate) on a back surface of the insulating substrate, and a hole pattern (a heat transfer member) provided in a portion of the insulating substrate under the upper layer plated pattern. The hole pattern is formed in a hole having one end inside the insulating substrate.

### BACKGROUND OF THE INVENTION

1. Field of the Invention

The present invention relates to a high frequency module. More specifically, the present invention relates to a high frequency module having an electronic component mounted on an insulating substrate on a heat sink plate.

2. Description of the Background Art

In a high frequency power module (hereafter referred to as a “high frequency module”) of high power which is mounted on a mobile or vehicle-mounted device used for radio communication, a matching circuit, for example, is connected to a high frequency amplification element which is die-bonded on a metal heat sink plate. The circuit is formed with an insulating substrate provided on the heat sink plate and having a circuit pattern formed on a top surface thereof, and mounted parts such as a capacitor and a coil which are mounted on the insulating substrate.

As higher power of the high frequency module has been required in these days, higher heat sink efficiency of the high frequency module as compared to a conventional one has been required.

FIG. 18 is a front cross-sectional view of an example of a conventional high frequency module.

Referring to FIG. 18, a high frequency module 101 includes an insulating substrate 105 provided on a metal heat sink plate 104 via a lower layer plated pattern 109, and a mounted part 106 provided on insulating substrate 105 via upper layer plated patterns 108A, 108B (signal lines). Mounted part 106 is connected to upper layer plated patterns 108A, 108B via solder 107. In addition, metal heat sink plate 104 is connected to a ground line.

FIG. 19 is a front cross-sectional view of another example of the conventional high frequency module.

Referring to FIG. 19, high frequency module 101 includes a through hole pattern 110 reaching lower layer plated pattern 109 on metal heat sink plate 104 in a portion of insulating substrate 105 near a joint portion between mounted part 106 and upper layer plated pattern 108A (an α3 portion in FIG. 19).

In FIG. 19, upper layer plated pattern 108A is a pattern which should be electrically connected to the ground line, and upper layer plated pattern 108B is a pattern which should be electrically connected to a signal line.

Upper layer plated pattern 108A is electrically connected to the ground line by providing through hole pattern 110. Since upper layer plated pattern 108B should be electrically connected to the signal line, through hole pattern 110 cannot be provided in a portion of insulating substrate 105 near a joint portion between mounted part 106 and upper layer plated pattern 108B (an α4 portion in FIG. 19).

Since the other portions are similar to those in FIG. 18, detailed descriptions thereof are not repeated.

Japanese Patent Laying-Open No. 09-252168 discloses a high frequency amplifier in which an insulating layer is provided on a metal substrate, a high frequency circuit is assembled on the insulating layer, the insulating layer is formed as a thin film in a portion for mounting a heat-producing element of the high frequency circuit, and the insulating layer is formed to have a thickness which can attain a desired impedance property in a portion for mounting a non-heat-producing element or the like.

In addition, Japanese Patent Laying-Open No. 09-008482 discloses a heat sink structure of a switching element including a glass epoxy substrate, a copper foil layer for dissipating heat formed inside the glass epoxy substrate, a surface copper foil layer formed on a surface of the glass epoxy substrate and connected with a back surface of the switching element, and a through hole extending from the surface copper foil layer to the copper foil layer for dissipating heat.

On the other hand, Japanese Patent Laying-Open No. 2001-156406 discloses a silicon nitride interconnection substrate formed with an interconnection circuit layer provided on one surface of an insulating substrate made of ceramic containing silicon nitride as a main component, and a heat sink plate affixed to the other surface of the insulating substrate, in which a via formation layer having a plurality of via conductors formed by filling of a conductor containing copper as a main component is provided on a side of the other surface of the insulating substrate, the via formation layer is thermally connected to the heat sink plate, and a thickness of the via formation layer on the insulating substrate is set from 30 percent to 80 percent of that of a whole insulating substrate.

In addition, Japanese Patent Laying-Open No. 2001-068878 discloses a control device in which an electronic circuit is formed on a substrate and connected with a conductor, which is characterized in that a metal core is arranged around a heat-producing portion of the electronic circuit.

The high frequency module as described above has problems as follows.

In a structure shown in FIG. 18, heat produced in a joint portion between mounted part 106 and solder 107 (α1 and α2 portions in FIG. 18) is conducted via insulating substrate 105 to metal heat sink plate 104, as indicated with a broken line arrow in FIG. 18. Since insulating substrate 105 generally has a thermal conductivity lower than that of a metal, sufficient heat sink efficiency may not be obtained in this structure.

In contrast, in a structure shown in FIG. 19, heat produced in the α3 portion is conducted via through hole pattern 110 to metal heat sink plate 104, as indicated with a solid line arrow in FIG. 19. Through hole pattern 110 has a thermal conductivity higher than that of insulating substrate 105, and sufficient heat sink efficiency in this portion is ensured.

Heat produced in the α4 portion in FIG. 19, however, is conducted via insulating substrate 105 to metal heat sink plate 104, as indicated with a broken line arrow in FIG. 19. Since insulating substrate 105 has a low thermal conductivity as described above, sufficient heat sink efficiency may not be obtained in this portion.

It may be possible to make insulating substrate 105 thinner to increase heat sink efficiency of high frequency module 101. When insulating substrate 105 is extremely thin, however, an interconnection width of a microstrip line formed on insulating substrate 105 becomes narrow and a gain of a circuit including the microstrip line is decreased, which sometimes makes it difficult to obtain desired power from an output terminal of high frequency module 101.

### SUMMARY OF THE INVENTION

An object of the present invention is to provide a high frequency module having high heat sink efficiency.

In one aspect, a high frequency module according to the present invention includes an insulating substrate, a signal line formed on a main surface of the insulating substrate and electrically connected to a high frequency circuit to transmit a high frequency signal, an electronic component mounted on the main surface of the insulating substrate and connected to the signal line, a heat sink plate on a back surface of the insulating substrate, and a heat transfer member provided in a portion of the insulating substrate under the signal line to fill a hole having one end inside the insulating substrate.

With this construction, heat produced in the electronic component can be efficiently transmitted to the heat sink plate via the heat transfer member.

The heat transfer member preferably has a plate-like portion extending in a direction parallel to the main surface of the insulating substrate in an end portion of the hole inside the insulating substrate.

With this, a thermal resistance in this heat sink path can further be decreased because an area of the heat transfer member contributing to reduction of the thermal resistance can be increased.

Preferably, a conductor portion is included in a through hole extending from the main surface of the insulating substrate to the heat sink plate, and the conductor portion electrically connects the electronic component with the heat sink plate.

With this construction, heat produced in the electronic component can be efficiently transmitted to the heat sink plate via the conductor portion.

A spacing between the holes is preferably smaller than a spacing between the through holes.

With this, heat sink efficiency of the heat sink path via the heat transfer member can be increased.

In another aspect, a high frequency module according to the present invention includes an insulating substrate, a signal line formed on a main surface of the insulating substrate and electrically connected to a high frequency circuit to transmit a high frequency signal, an electronic component mounted on the main surface of the insulating substrate and connected to the signal line, a heat sink plate on a back surface of the insulating substrate, and a heat transfer member provided in a portion of the insulating substrate under the signal line.

In this aspect, heat produced in the electronic component can be efficiently transmitted to the heat sink plate via the heat transfer member.

In a still another aspect, a high frequency module according to the present invention includes an insulating substrate, a signal line formed on a main surface of the insulating substrate and electrically connected to a high frequency circuit to transmit a high frequency signal, an electronic component mounted on the main surface of the insulating substrate and connected to the signal line, a heat sink plate on a back surface of the insulating substrate, a heat transfer member provided in a portion of the insulating substrate under the signal line to fill a hole having one end inside the insulating substrate, and a metal block provided on the signal line.

In a further aspect, a high frequency module according to the present invention includes an insulating substrate, a signal line formed on a main surface of the insulating substrate and electrically connected to a high frequency circuit to transmit a high frequency signal, an electronic component mounted on the main surface of the insulating substrate and having an electrode portion connected to the signal line provided on the main surface of the insulating substrate, a heat sink plate on a back surface of the insulating substrate, and a metal block provided on the signal line to cover a side surface of the electrode portion in a direction of a height thereof.

Heat produced in the electronic component can be reliably transmitted to the signal line on the insulating substrate by providing the metal block. As a result, heat sink efficiency of this path is increased.

As described above, according to the present invention, heat produced in the electronic component can be efficiently transmitted to a metal plate provided on the back surface of the insulating substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic top plan view of a high frequency module according to first to third embodiments of the present invention.

FIG. 2 is a front cross-sectional view of the high frequency module according to the first embodiment of the present invention.

FIG. 3 is a cross-sectional view taken along the line III-III in FIG. 2.

FIG. 4 is a cross-sectional view taken along the line IV-IV in FIG. 2.

FIG. 5 is a cross-sectional view taken along the line V-V in FIGS. 2 and 6.

FIG. 6 is a front cross-sectional view of the high frequency module according to the second embodiment of the present invention.

FIG. 7 is a cross-sectional-view taken along the line VII-VII in FIG. 6.

FIG. 8 is a cross-sectional view taken along the line VIII-VIII in FIG. 6.

FIG. 9 is a front cross-sectional view of a modified example of the high frequency module according to the second embodiment of the present invention.

FIG. 10 is a front cross-sectional view of another modified example of the high frequency module according to the second embodiment of the present invention.

FIG. 11 is a front cross-sectional view of a still another modified example of the high frequency module according to the second embodiment of the present invention.

FIG. 12 is a front cross-sectional view of a further modified example of the high frequency module according to the second embodiment of the present invention.

FIG. 13 is a front cross-sectional view of the high frequency module according to the third embodiment of the present invention.

FIG. 14 is a cross-sectional view taken along the line XIV-XIV in FIG. 13.

FIG. 15 is a front cross-sectional view of a modified example of the high frequency module according to the third embodiment of the present invention.

FIG. 16 is a front cross-sectional view of another modified example of the high frequency module according to the third embodiment of the present invention.

FIG. 17 is a front cross-sectional view of a further modified example of the high frequency module according to the third embodiment of the present invention.

FIG. 18 is a front cross-sectional view of an example of a conventional high frequency module.

FIG. 19 is a front cross-sectional view of another example of the conventional high frequency module.

FIG. 20 indicates a model applied to thermal resistance calculation.

FIG. 21 is a cross-sectional view taken along the line XXI-XXI in FIG. 20.

FIG. 22 is a cross-sectional view of an insulating substrate having an internal layer plated pattern formed therein.

### DESCRIPTION OF THE PREFERRED EMBODIMENTS

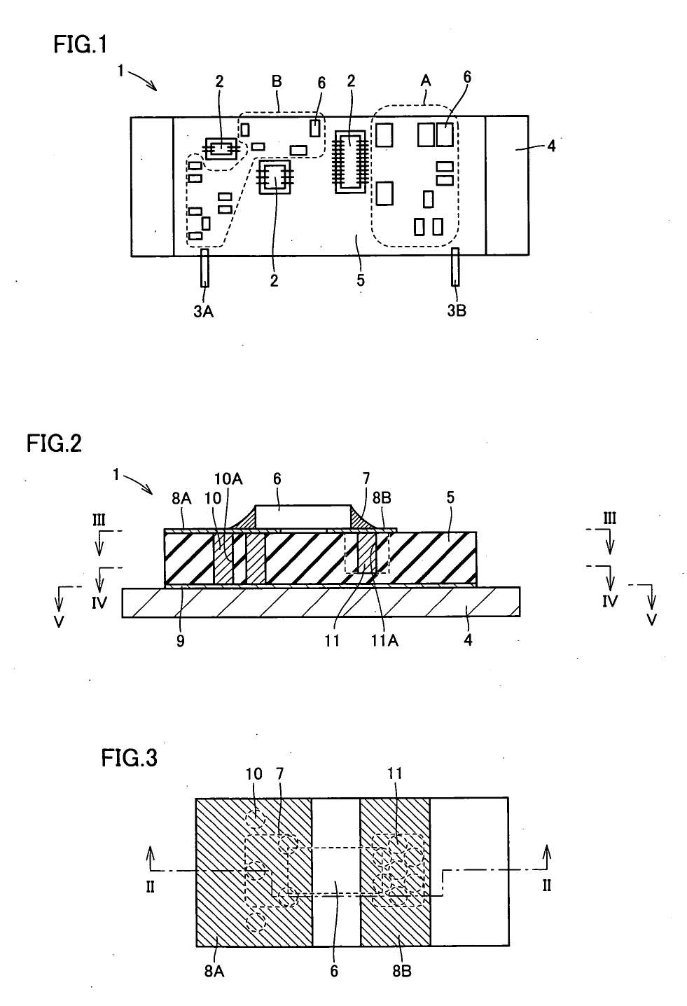

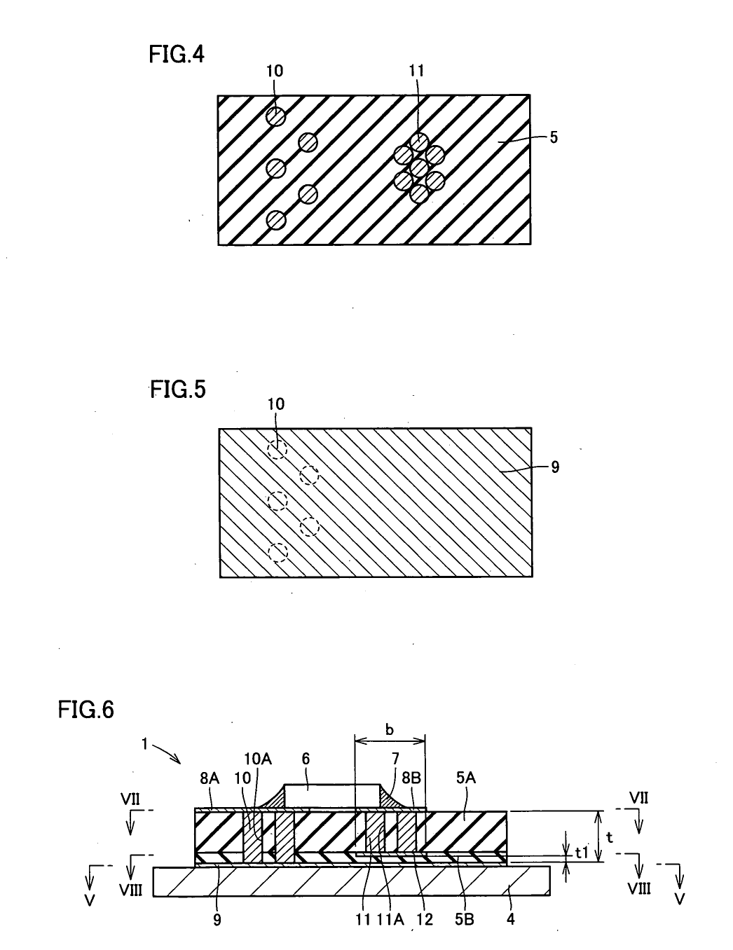

Embodiments (first to third embodiments) of a high frequency module according to the present invention will be described in the following using FIGS. 1 to 17.

Referring to FIG. 1, a high frequency module 1 includes a high frequency amplification element 2 die-bonded on a metal heat sink plate 4, an insulating substrate 5 affixed to the metal heat sink plate using solder, and a mounted part 6 mounted on insulating substrate 5.

Copper, for example, is used as metal heat sink plate 4. Insulating substrate 5 and mounted part 6 form a circuit such as a matching circuit or a bias circuit. A capacitor, a coil or a resistance, for example, is used as mounted part 6. In addition, a glass epoxy resin substrate or the like is typically used as insulating substrate 5. A manufacturing cost of the high frequency module can be reduced using the glass epoxy resin. A thermosetting PPO (Poly Phenylene Oxide) resin or a ceramic substrate, for example, can be used in place of the glass epoxy resin substrate.

High frequency module 1 is incorporated into, for example, a mobile or vehicle-mounted radio. The radio is typically a mobile station, and high frequency module 1 functions as a transmission amplifier for launching a radio wave into an aerial inside the radio.

The transmission amplifier is required to have electrical performance such as robustness against a load change (a load change property). The load change property is evaluated by performing a test (a load change test) in which a load not matching with a nominal output resistance (for example, about 50 Ω) is provided to a high frequency output terminal 3B of the high frequency module during an operation of the high frequency module to examine as to, for example, whether high frequency module 1 has deteriorated performance or is damaged.

During the load change test, mounted part 6 on insulating substrate 5 produces heat. It is preferable to efficiently dissipate the heat in order to suppress deterioration of performance or a decrease in reliability of mounted part 6. The load change test is an example of causes of heat production of mounted part 6, and heat production of mounted part 6 also occurs by a cause other than the load change test (for example, energization during a normal use).

Though high frequency amplification element 2 is a large heat source, it has a sufficient heat sink property because it is die-bonded on metal heat sink plate 4. In contrast, mounted part 6 mounted on insulating substrate 5 having a low thermal conductivity cannot obtain a sufficient heat sink property.

In FIG. 1, mounted part 6 located in a region (a region B in FIG. 1) on a side of a high frequency input terminal 3A produces a relatively small amount of heat, while mounted part 6 located in a region (a region A in FIG. 1) on a side of high frequency output terminal 3B produces a relatively large amount of heat. Therefore, heat sink efficiency must be increased especially in region A.

High frequency module 1 according to each embodiment described below has a construction for easily conducting heat produced in mounted part 6 to metal heat sink plate 4. With this, reliability of high frequency module 1 can be increased.

(First Embodiment)

FIG. 2 is a cross-sectional view taken along the line II-II in FIG. 3. It is to be noted that, mounted part 6 on insulating substrate 5 in each drawing described below is indicated largely as compared to that in FIG. 1 for convenience of description.

Referring to FIGS. 2 to 5, high frequency module 1 includes insulating substrate 5 provided on metal heat sink plate 4 via a lower layer plated pattern 9, and mounted part 6 provided on insulating substrate 5 via upper layer plated patterns 8A, 8B. Mounted part 6 is connected to upper layer plated patterns 8A, 8B via a solder 7. In addition, metal heat sink plate 4 is connected to a ground line.

High frequency module 1 has a through hole 10A reaching lower layer plated pattern 9 on metal heat sink plate 4, which is provided in a portion of insulating substrate 5 near a joint portion between mounted part 6 and upper layer plated pattern 8A. A through hole pattern 10 is provided in through hole 10A.

In each of FIGS. 2 to 5, upper layer plated pattern 8A is a pattern which should be electrically connected to the ground line, and upper layer plated pattern 8B is a pattern which should be electrically connected to a signal line.

Upper layer plated pattern 8A is electrically connected to the ground line by providing through hole pattern 10. Since upper layer plated pattern 8B should be electrically connected to the signal line, through hole pattern 10 cannot be provided in a portion of insulating substrate 5 near a joint portion between mounted part 6 and upper layer plated pattern 8B.

In a construction described above, heat produced in a connection portion between mounted part 6 and upper layer plated pattern 8A is conducted to lower layer plated pattern 9 and metal heat sink plate 4 via through hole pattern 10. Since through hole pattern 10 includes a metal, a thermal resistance in this path is sufficiently low.

On the other hand, a heat sink path for heat produced in a connection portion between mounted part 6 and upper layer plated pattern 8B becomes a concern. As described above, when the heat is conducted to metal heat sink plate 4 via a whole thickness of insulating substrate 5, a thermal resistance in this path becomes high because insulating substrate 5 has a low thermal conductivity.

To solve this problem, a substrate having a relatively high thermal conductivity can be used as insulating substrate 5. A substrate made of ceramic, for example, can be used as such insulating substrate. A material as such, however, is generally relatively expensive and is disadvantageous in terms of a cost.

Therefore, in this embodiment, a glass epoxy resin substrate which requires a relatively low cost is used as insulating substrate 5, and a hole 11A is provided in a portion of insulating substrate 5 near the connection portion between mounted part 6 and upper layer plated pattern 8B, in which hole 11A a hole pattern 11 is provided.

By providing hole pattern 11, a thickness of the insulating substrate involved in the heat sink path for heat produced in the connection portion between mounted part 6 and upper layer plated pattern 8B is decreased. With this, the thermal resistance in this heat sink path can be decreased.

Through hole pattern 10 and hole pattern 11 are formed using a material having a high thermal conductivity such as copper.

In consideration of the thermal conductivity, through hole pattern 10 and hole pattern 11 typically fill through hole 10A and hole 11A, respectively, but they may be provided on, for example, only peripheries of through hole 10A and hole 11A. In addition, a term “filling” used herein means filling to such an extent that thermal conductivities of patterns 10, 11 can be increased, and it should be understood that a void may be included therein in some degree.

The construction described above can be explained in other words as follows. That is, high frequency module 1 according to this embodiment includes insulating substrate 5, upper layer plated pattern 8B (a signal line) formed on a main surface of insulating substrate 5 and electrically connected to a high frequency circuit to transmit a high frequency signal, mounted part 6 (an electronic component) mounted on the main surface of insulating substrate 5 and connected to upper layer plated pattern 8B, metal heat sink plate 4 (a heat sink plate) on a back surface of insulating substrate 5, and hole pattern 11 (a heat transfer member) provided in a portion of insulating substrate 5 under upper layer plated pattern 8B. Hole pattern 11 is formed in hole 11A having one end inside insulating substrate 5.

With this construction, heat produced between the high frequency circuit and mounted part 6 can be efficiently transmitted to metal heat sink plate 4 via hole pattern 11.

Through hole pattern 10 (a conductor portion) is included in through hole 10A extending from the main surface of insulating substrate 5 to metal heat sink plate 4, which through hole pattern 10 electrically connects mounted part 6 with metal heat sink plate 4.

With this construction, heat produced in mounted part 6 can be efficiently transmitted to metal heat sink plate 4 via through hole pattern 10.

For allowing hole pattern 11 to efficiently function as the heat transfer member, hole patterns 11 are preferably provided with at least a certain density. In this embodiment, a spacing between holes 11A is smaller than a spacing between through holes 10A. With this, heat sink efficiency of the heat sink path via hole pattern 11 can be increased. It is to be noted that, the spacing between the holes (through holes 10A and holes 11A) used herein means a distance between respective centers of the holes adjacent to each other.

(Second Embodiment)

Referring to FIG. 6, high frequency module 1 according to this embodiment is a modified example of the high frequency module according to the first embodiment, which is different from the first embodiment in that an internal layer plated pattern 12 (a plate-like portion) extending in a direction parallel to the main surface of insulating substrate 5 is included as a heat transfer member in an end portion of hole 11A inside insulating substrate 5.

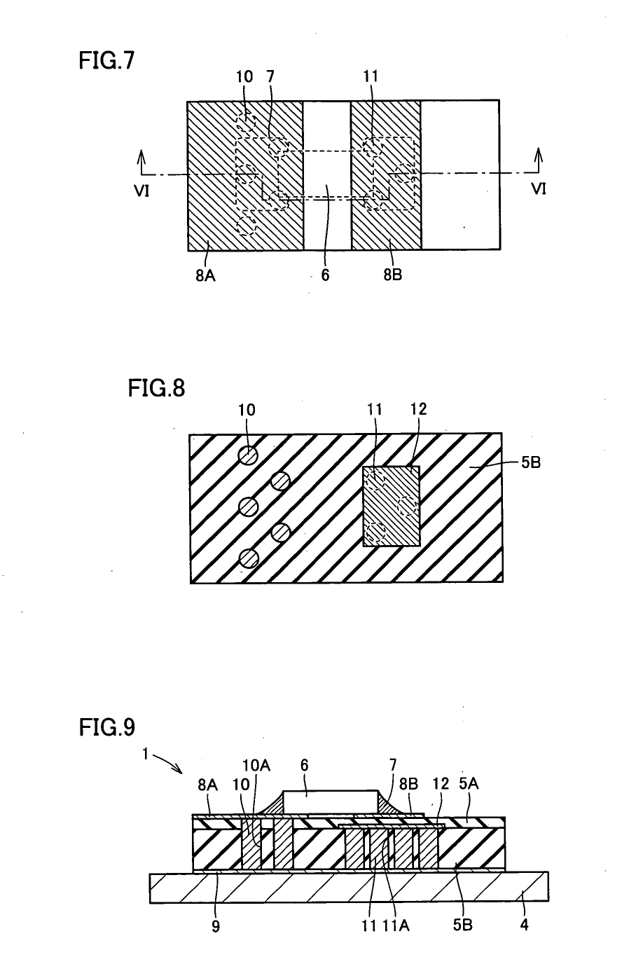

Referring to FIG. 7, a spacing between hole patterns 11 in this embodiment is larger than that in the first embodiment.

Referring to FIG. 8, internal layer plated pattern 12 has widths in vertical and horizontal directions in FIG. 8 larger than those of hole pattern 11. In addition, internal layer plated pattern 12 is formed to cover a plurality of hole patterns 11.

A cross section taken along the line V-V is similar to that in the first embodiment.

An area of the heat transfer member opposed to metal heat sink plate 4 can be increased by providing internal layer plated pattern 12 as described above. Therefore, a thermal resistance in a heat sink path via the heat transfer member can be decreased corresponding to an area of internal layer plated pattern 12.

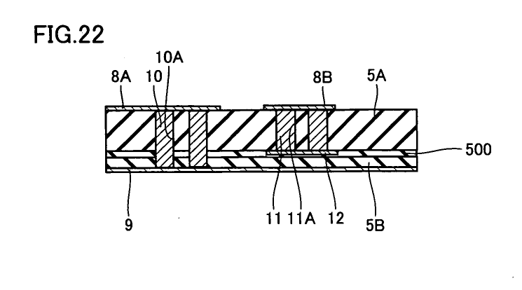

An example of a method of forming internal layer plated pattern 12 is described using FIG. 22. First, a through hole corresponding to hole 11A is provided in an insulating substrate 5A, and after plating both surfaces of the substrate with copper, etching is performed. With this, patterns corresponding to upper layer plated patterns 8A, 8B and a pattern corresponding to internal layer plated pattern 12 are respectively formed on both surfaces of insulating substrate 5A, and hole pattern 11 is formed in hole 11A.

Then, insulating substrates 5A, 5B are affixed to each other via an adhesive layer 500 to bond both substrates. Adhesive layer 500, which is formed by thermally curing an insulating adhesive, has a thickness smaller than those of insulating substrates 5A, 5B and larger than that of internal layer plated pattern 12.

A through hole corresponding to through hole 10A is further provided in bonded insulating substrate 5 (5A, 5B). Thereafter, a surface on a side of insulating substrate 5B is plated with copper, and etching of the surface is performed to form lower layer plated pattern 9. Then, surface polishing is performed for upper layer and lower layer plated patterns 8A, 8B, 9. The insulating substrate having internal layer plated pattern 12 as shown in FIG. 22 is formed by steps described above.

It is to be noted that, though internal layer plated pattern 12 (12A, 12B) indicated in each of FIG. 6 and FIGS. 9 to 12 described below is formed by a method similar to that described above, adhesive layer 500 is included in insulating substrates 5A, 5B, 5C and is not shown in these drawings for convenience of indication and description.

A construction of high frequency module 1 according to this embodiment has been described above. Since the other portions are similar to those in the first embodiment, descriptions thereof are not repeated.

An effect obtained with the construction of the high frequency module according to this embodiment will now be described.

Referring to FIG. 20, a heat source 80 having a length of a on a long side and a length of b on a short side is mounted on a heat conducting material 50 having a thickness of t.

Referring to FIG. 21, in this model, heat of heat source 80 is transmitted with spreading at an angle of 45°. This model is widely used in calculation of a thermal resistance of an IC (Integrated Circuit) or the like.

In the model shown in FIGS. 20 and 21, a thermal resistance Rₒ (K/W) is obtained with the following approximate expression (expression 1).
Rₒ=(1/λ)×(½(a−b))×ln(a(b+2t)/b(a+2t))

Herein, λ (W/mK) indicates a thermal conductivity of heat conducting material 50. The approximate expression is described in, for example, “GaAs DENKAIKOUKA TORANJISUTA NO KISO (Fundamentals of GaAs Field Effect Transistor)” written by Masumi Fukuda and Yasutaka Hirachi (edited by The Institute of Electronics, Information and Communication Engineers).

Next, a thermal resistance in a heat sink path via hole pattern 11 and internal layer plated pattern 12 in a structure shown in FIG. 6 is calculated using a thermal resistance calculation model described above.

In the structure shown in FIG. 6, insulating substrate 5B corresponds to heat conducting material 50 and internal layer plated pattern 12 corresponds to heat source 80. Characteristics regarding materials, sizes and the like in the structure shown in FIG. 6 are as indicated in Table 1.

TABLE 1

| | | |
|---|---|---|
| Member | Material | Value |

| | | | |
|---|---|---|---|
| Heat Source | Copper Plating | a (mm) | 2.8 |
| | | b (mm) | 2.0 |
| Heat Conducting | Glass Epoxy Resin | λ (W/mK) | 0.4 |
| Material | | t1 (mm) | 0.1 |

Substituting each value of Table 1 in the above-described approximate expression for obtaining the thermal resistance yields Rₒ of about 41 (K/W).

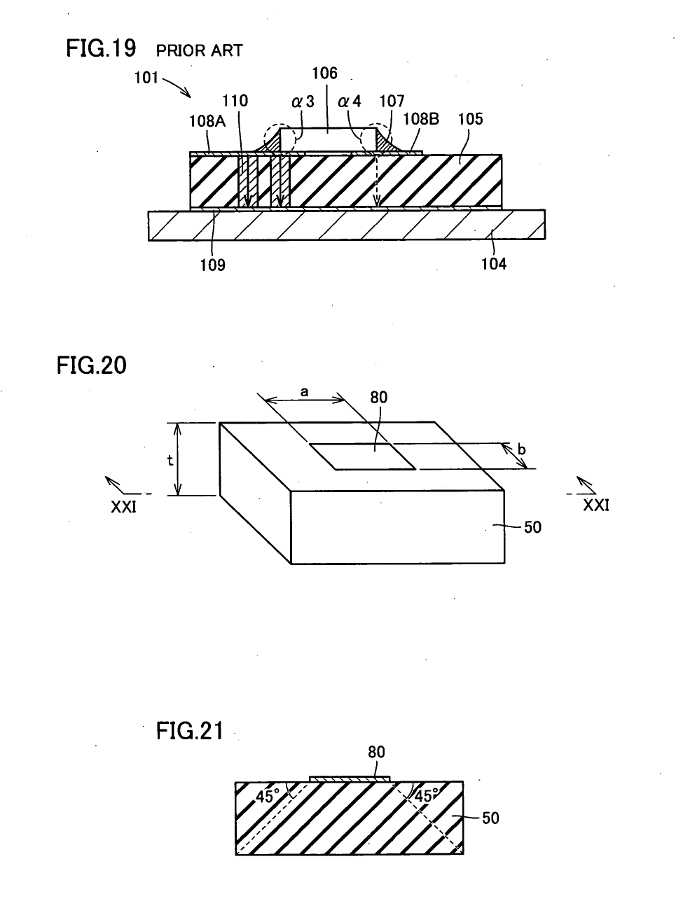

In contrast, in a conventional structure shown in FIGS. 18 and 19, insulating substrate 105 corresponds to heat conducting material 50 and upper layer plated pattern 108B corresponds to heat source 80. Characteristics regarding materials, sizes and the like in the structure shown in FIGS. 18 and 19 are as indicated in Table 2.

TABLE 2

| | | |
|---|---|---|
| Member | Material | Value |

| | | | |
|---|---|---|---|
| Heat Source | Copper Plating | a (mm) | 2.8 |
| | | b (mm) | 2.0 |
| Heat Conducting | Glass Epoxy Resin | λ (W/mK) | 0.4 |
| Material | | t (mm) | 0.6 |

Substituting each value of Table 2 in the above-described approximate expression for obtaining the thermal resistance yields Rₒ of about 177 (K/W).

Therefore, it becomes apparent that, in the high frequency module according to this embodiment, the heat sink path for transmitting heat produced in a portion of mounted part 6 near the signal line to metal heat sink plate 4 has a thermal resistance lower than that in the conventional structure.

It is to be noted that, a thermal resistance in a heat sink path extending from upper layer plated pattern 8B to internal layer plated pattern 12 in FIG. 6 is sufficiently lower than that in a heat sink path via insulating substrate 5. Therefore, consideration of the thermal resistance in this portion is not necessary in calculation of the thermal resistance described above.

In addition, a parasitic capacitance is formed between internal layer plated pattern 12 and lower layer plated pattern 9 by adopting the structure as shown in FIG. 6. When the capacitance is large, it may affect a high frequency matching circuit or the like which is formed on a main surface of insulating substrate 5.

In the high frequency module according to this embodiment, when a capacitor is provided as mounted part 6, a capacity of the capacitor is sufficiently larger than the parasitic capacitance. More specifically, in contrast to the capacitor on the insulating substrate having the capacity of, for example, about 200 (pF), the parasitic capacitance formed between internal layer plated pattern 12 and lower layer plated pattern 9 is, for example, about 2.4 (pF). In the conventional structure (see FIGS. 18 and 19), a parasitic capacitance formed between upper layer plated pattern 8B and lower layer plated pattern 9 is, for example, about 0.4 (pF).

As described above, an amount of the parasitic capacitance is negligible in this embodiment.

Referring to FIG. 9, hole pattern 11 is provided in a portion under upper layer plated pattern 8B, and extends from the back surface of insulating substrate 5 to a portion near the main surface of insulating substrate 5. In addition, internal layer plated pattern 12 is provided in a portion between hole pattern 11 and upper layer plated pattern 8B opposed to each other.

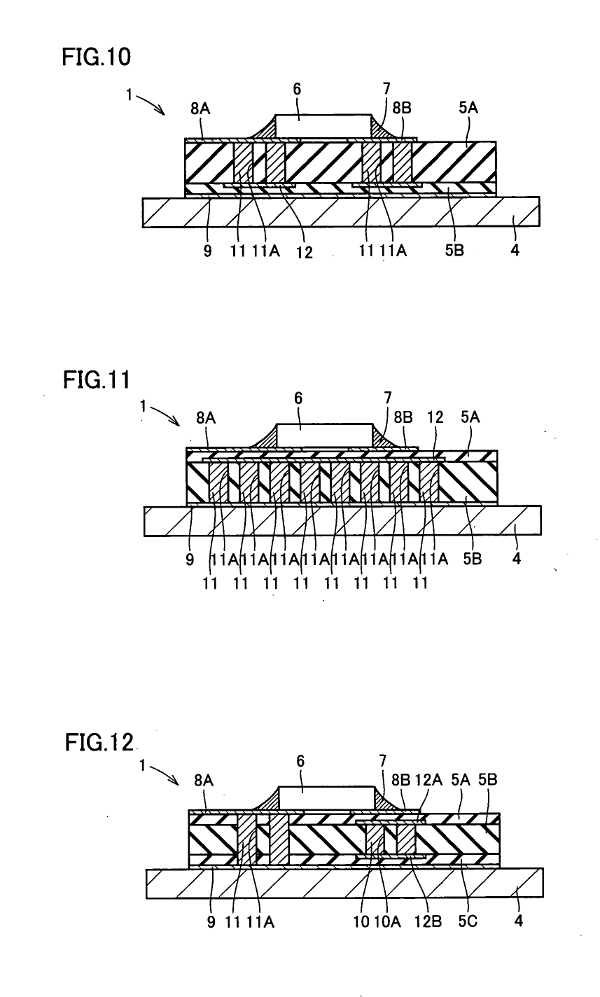

Referring to FIG. 10, hole pattern 11 is provided in a portion under each of upper layer plated patterns 8A, 8B, and extends from the main surface of insulating substrate 5 to a portion near the back surface of insulating substrate 5. In addition, internal layer plated pattern 12 is provided in a portion between hole pattern 11 and lower layer plated pattern 9 opposed to each other.

Referring to FIG. 11, hole pattern 11 is provided in a whole region of insulating substrate 5, and extends from the back surface of insulating substrate 5 to a portion near the main surface of insulating substrate 5. In addition, internal layer plated pattern 12 is provided between hole pattern 11 and the main surface of insulating substrate 5.

In FIGS. 9 to 11, insulating substrate 5 is formed with insulating substrates 5A, 5B, while insulating substrate 5 is formed with insulating substrates 5A, 5B, 5C in FIG. 12. Since a method of forming insulating substrate 5 as such is similar to that described above, a description thereof is not repeated.

Referring to FIG. 12, hole pattern 11 is provided in a portion under upper layer plated pattern 8B, and extends from a portion near the main surface of insulating substrate 5 to a portion near the back surface of insulating substrate 5. In addition, internal layer plated pattern 12 is provided in a portion between hole pattern 11 and each of upper layer plated pattern 8B and lower layer plated pattern 9, which are opposed to each other.

In a structure shown in each of FIGS. 9 to 12, heat produced in mounted part 6 can also be efficiently transmitted to metal heat sink plate 4.

(Third Embodiment)

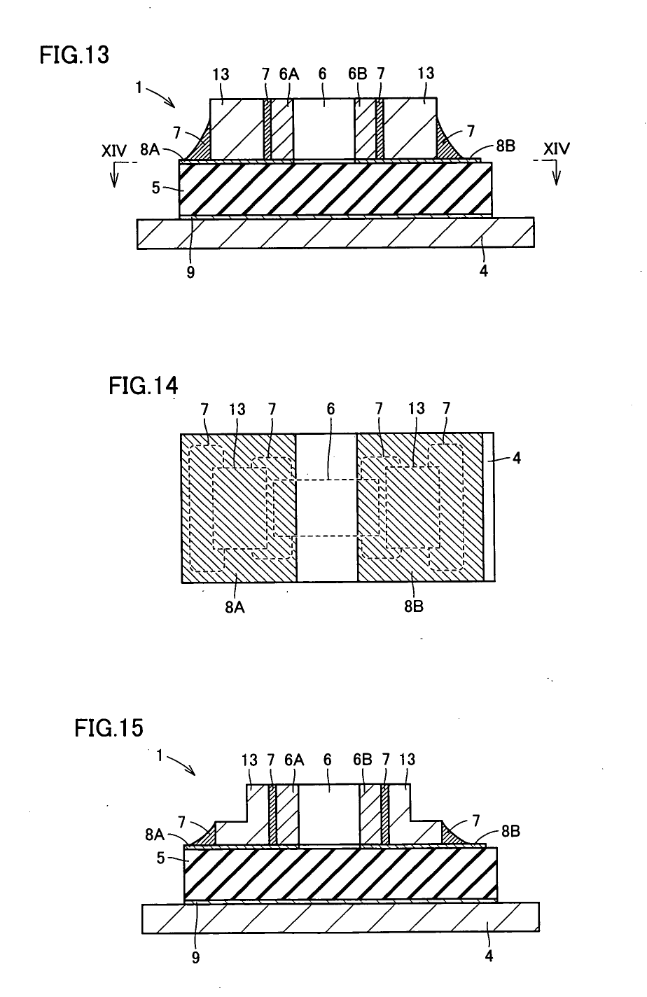

Referring to FIGS. 13 and 14, a high frequency module according to this embodiment includes insulating substrate 5, upper layer plated patterns 8A, 8B (signal lines) formed on a main surface of insulating substrate 5 and electrically connected to a high frequency circuit to transmit a high frequency signal, mounted part 6 (an electronic component) mounted on the main surface of insulating substrate 5 and having electrodes 6A, 6B (electrode portions) connected to upper layer plated patterns 8A, 8B provided on the main surface of insulating substrate 5, metal heat sink plate 4 (a heat sink plate) on a back surface of insulating substrate 5, and a metal block 13 provided on upper layer plated patterns 8A, 8B to cover side surfaces of electrodes 6A, 6B in a direction of a height thereof (a vertical direction in FIG. 13).

Copper, for example, can be used as metal block 13. The side surfaces of electrodes 6A, 6B used herein mean end surfaces of electrodes 6A, 6B in a horizontal direction in FIG. 13.

When metal block 13 is not provided in a structure shown in FIGS. 13 and 14, heat produced in electrode portions 6A, 6B is transmitted via solder 7 to upper layer plated patterns 8A, 8B, and then transmitted through insulating substrate 5 toward metal heat sink plate 4. Therefore, a contact area between solder 7 and upper layer plated patterns 8A, 8B has an effect on a thermal resistance in this heat sink path.

With metal block 13 provided together with solder 7 in this construction, heat can be transferred to upper layer plated patterns 8A, 8B via solder 7 and metal block 13. A contact area between metal block 13 and upper layer plated patterns 8A, 8B can be more stably ensured as compared to the contact area between solder 7 and upper layer plated patterns 8A, 8B. Therefore, heat produced in mounted part 6 can be reliably transmitted to upper layer plated patterns 8A, 8B on insulating substrate 5. As a result, heat sink efficiency of this path is increased.

Referring to FIG. 15, a cross section of metal block 13 may have, for example, an L-like shape.

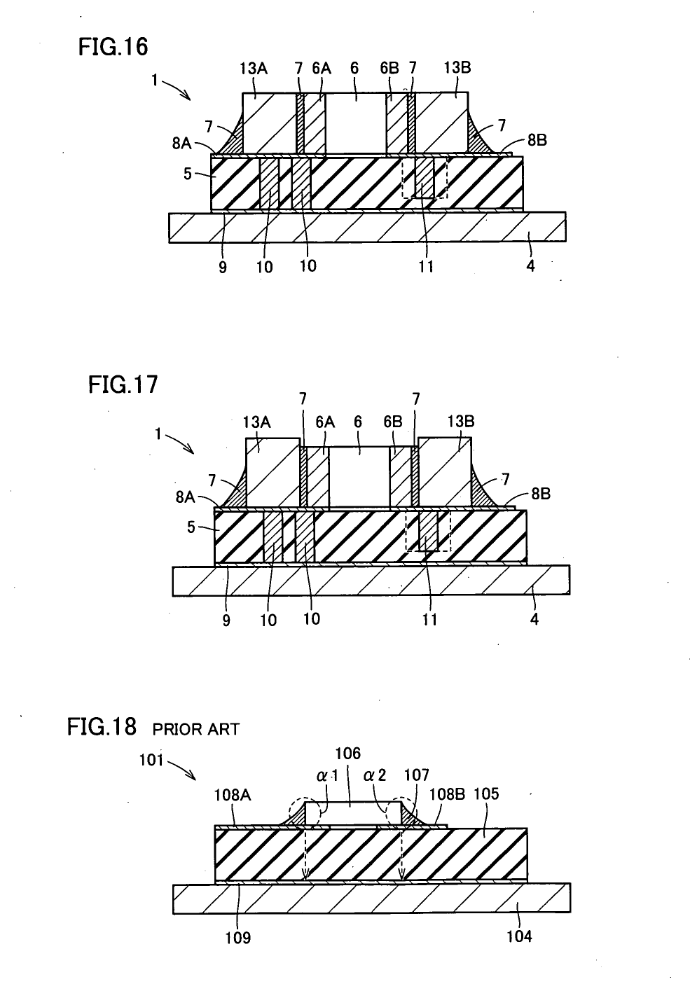

Referring to FIG. 16, metal block 13 may be applied to the high frequency module according to the first embodiment described above.

A structure shown in FIG. 16 can be explained in other words as follows. That is, a modified example of the high frequency module according to this embodiment includes insulating substrate 5, upper layer plated pattern 8B (a signal line) formed on a main surface of insulating substrate 5 and electrically connected to a high frequency circuit to transmit a high frequency signal, mounted part 6 (an electronic component) mounted on the main surface of insulating substrate 5 and connected to upper layer plated pattern 8B, metal heat sink plate 4 (a heat sink plate) on a back surface of insulating substrate 5, and hole pattern 11 (a heat transfer member) provided in a portion of insulating substrate 5 under upper layer plated pattern 8B to fill a hole having one end inside insulating substrate 5, wherein electrodes 6A, 6B of mounted part 6 are respectively connected to upper layer plated patterns 8A, 8B, a metal block 13A is provided on upper layer plated pattern 8A, and a metal block 13B is provided on upper layer plated pattern 8B. Upper layer plated pattern 8A is connected to lower layer plated pattern 9 via through hole pattern 10. Lower layer plated pattern 9 is connected to a ground line via metal heat sink plate 4.

It is to be noted that, in this embodiment, metal block 13A provided on upper layer plated pattern 8A is not an essential element, and the structure may have only metal block 13B provided on upper layer plated pattern 8B (the signal line).

Referring to FIG. 17, a height of metal block 13 (13A, 13B) may be larger than a height of electrodes 6A, 6B. The heights of metal block 13 and electrodes 6A, 6B used herein mean respective lengths of these elements in a vertical direction in FIG. 17.

Though the embodiments of the present invention have been described above, it is also naturally expected to combine characteristic portions of respective embodiments as required.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A high frequency module, comprising:
an insulating substrate;
a signal line formed on a main surface of said insulating substrate and electrically connected to a high frequency circuit to transmit a high frequency signal;
an electronic component mounted on the main surface of said insulating substrate and connected to said signal line;
a heat sink plate on a back surface of said insulating substrate; and
a heat transfer member provided in a portion of said insulating substrate under said signal line to fill a hole having one end inside said insulating substrate.

2. The high frequency module according to claim 1, wherein
said heat transfer member has a plate-like portion extending in a direction parallel to the main surface of said insulating substrate in an end portion of said hole inside said insulating substrate.

3. The high frequency module according to claim 1, further comprising
a conductor portion in a through hole extending from the main surface of said insulating substrate to said heat sink plate, wherein
said conductor portion electrically connects said electronic component with said heat sink plate.

4. The high frequency module according to claim 3, wherein
a spacing between said holes is smaller than a spacing between said through holes.

5. A high frequency module, comprising:
an insulating substrate;
a signal line formed on a main surface of said insulating substrate and electrically connected to a high frequency circuit to transmit a high frequency signal;
an electronic component mounted on the main surface of said insulating substrate and connected to said signal line;
a heat sink plate on a back surface of said insulating substrate; and
a heat transfer member provided in a portion of said insulating substrate under said signal line.

6. A high frequency module, comprising:
an insulating substrate;
a signal line formed on a main surface of said insulating substrate and electrically connected to a high frequency circuit to transmit a high frequency signal;
an electronic component mounted on the main surface of said insulating substrate and connected to said signal line;
a heat sink plate on a back surface of said insulating substrate;
a heat transfer member provided in a portion of said insulating substrate under said signal line to fill a hole having one end inside said insulating substrate; and
a metal block provided on said signal line.

7. A high frequency module, comprising:
an insulating substrate;
a signal line formed on a main surface of said insulating substrate and electrically connected to a high frequency circuit to transmit a high frequency signal;
an electronic component mounted on the main surface of said insulating substrate and having an electrode portion connected to said signal line provided on the main surface of said insulating substrate;
a heat sink plate on a back surface of said insulating substrate; and
a metal block provided on said signal line to cover a side surface of said electrode portion in a direction of a height thereof.
